(19) United States
(12) Patent Application Publication
(10) Pub. No.: US 2024/0175127 A1
(43) Pub. Date: May 30, 2024

(54) PROCESSING APPARATUS AND PROCESSING METHOD

(71) Applicant: Tokyo Electron Limited, Tokyo (JP)

(72) Inventor: Masami OIKAWA, Oshu City (JP)

(21) Appl. No.: 18/513,994

(22) Filed: Nov. 20, 2023

(30) Foreign Application Priority Data
Nov. 25, 2022 (JP) 2022-188318

(51) Int. Cl. C23C 16/44

(52) U.S. Cl. CPC C23C 16/4412; C23C 16/4405

(57) ABSTRACT

A processing apparatus includes: a processing container configured to be depressurized; a film formation gas supply path configured to supply a film formation gas into the processing container; an exhaust pipe connected to the processing container and configured to exhaust the film formation gas in the processing container; a branch pipe branching from the exhaust pipe; and a diaphragm vacuum gauge connected to the branch pipe, wherein at least one of the exhaust pipe or the branch pipe has an inner surface where a material that promotes consumption of the film formation gas is exposed.

### CROSS-REFERENCE TO RELATED APPLICATION

This application is based upon and claims the benefit of priority from Japanese Patent Application No. 2022-188318, filed on Nov. 25, 2022, the entire contents of which are incorporated herein by reference.

### TECHNICAL FIELD

The present disclosure relates to a processing apparatus and a processing method.

### BACKGROUND

A diaphragm vacuum gauge equipped with a diaphragm is sometimes used to measure a pressure inside a vacuum chamber. Patent Document 1 discloses a technique in which a baffle is provided to suppress contamination of a diaphragm by gases and particles.

### PRIOR ART DOCUMENT

### Patent Document

Patent Document 1: Japanese Patent Laid-Open Publication No. 2009-524024

### SUMMARY

According to one aspect of the present disclosure, a processing apparatus includes: a processing container configured to be depressurized; a film formation gas supply path configured to supply a film formation gas into the processing container; an exhaust pipe connected to the processing container and configured to exhaust the film formation gas in the processing container; a branch pipe branching from the exhaust pipe; and a diaphragm vacuum gauge connected to the branch pipe, wherein at least one of the exhaust pipe or the branch pipe has an inner surface where a material that promotes consumption of the film formation gas is exposed.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic view illustrating a processing apparatus according to a first embodiment.

FIG. 2 is a schematic view illustrating a diaphragm vacuum gauge.

FIG. 3 is a schematic view illustrating a processing method according to the first embodiment.

FIG. 4 is a schematic view illustrating a processing apparatus according to a second embodiment.

FIG. 5 is a schematic view illustrating a processing method according to the second embodiment.

FIG. 6 is a schematic view illustrating a processing method according to the second embodiment.

FIG. 7 is a schematic view illustrating a processing method according to the second embodiment.

FIG. 8 is a schematic view illustrating a processing apparatus according to a third embodiment.

FIG. 9 is a schematic view illustrating a processing method according to the third embodiment.

FIG. 10 is a schematic view illustrating a processing method according to the third embodiment.

FIG. 11 is a schematic view illustrating a processing method according to the third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting embodiments of the present disclosure will be described with reference to the accompanying drawings. In the drawings, the same reference numerals will be given to the same or corresponding components, and descriptions thereof will be omitted.

### First Embodiment

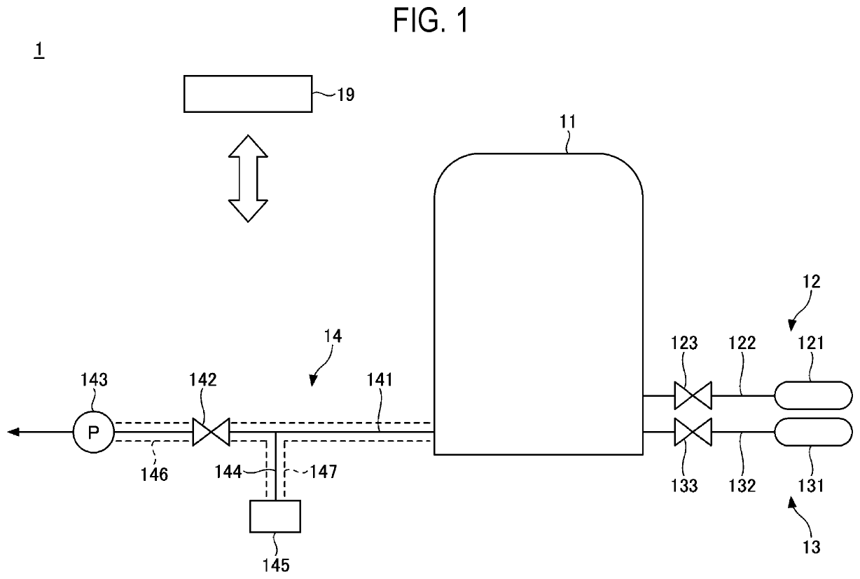

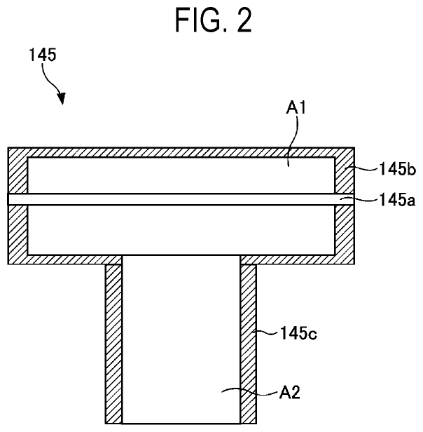

A processing apparatus 1 according to a first embodiment will be described with reference to FIGS. 1 and 2. FIG. 1 is a schematic view illustrating a processing apparatus 1 according to the first embodiment. FIG. 2 is a schematic view illustrating a diaphragm vacuum gauge 145. As illustrated in FIG. 1, the processing apparatus 1 includes a processing container 11, a film formation gas supply 12, a cleaning gas supply 13, an exhauster 14, and a controller 19.

An interior of the processing container 11 can be depressurized. The processing container 11 accommodates a substrate. Inside the processing container 11, various processes are performed on the substrate accommodated therein. Various processes include, for example, a film formation process. Various processes may include an etching process. The processing container 11 may be configured to accommodate one substrate or a plurality of substrates.

The film formation gas supply 12 includes a film formation gas source 121, a film formation gas supply path 122, and an opening/closing valve 123. The film formation gas supply 12 supplies a film formation gas from the film formation gas source 121 into the processing container 11 via the film formation gas supply path 122. The opening/closing valve 123 switches between supply and stop of the film formation gas into the processing container 11. A type of the film formation gas is not particularly limited. The film formation gas may be, for example, a silane-based gas such as monosilane (SiH₄) or disilane (Si₂H₆).

The cleaning gas supply 13 includes a cleaning gas source 131, a cleaning gas supply path 132, and an opening/closing valve 133. The cleaning gas supply 13 supplies a cleaning gas from the cleaning gas source 131 into the processing container 11 via the cleaning gas supply path 132. The opening/closing valve 133 switches between supply and stop of the cleaning gas into the processing container 11. The cleaning gas is a gas capable of removing deposits deposited in the processing container 11 due to the film formation process. For example, when the film formation gas is a silane-based gas, the cleaning gas may be fluorine gas.

The exhauster 14 includes an exhaust pipe 141, an opening/closing valve 142, a vacuum pump 143, a branch pipe 144, a diaphragm vacuum gauge 145, and pipe heaters 146 and 147.

The exhaust pipe 141 is connected to the processing container 11. The exhaust pipe 141 exhausts the film formation gas and the cleaning gas inside the processing container 11.

The opening/closing valve 142 is provided in the exhaust pipe 141. The opening/closing valve 142 adjusts an exhaust speed by adjusting a conductance of the exhaust pipe 141.

The vacuum pump 143 is provided in the exhaust pipe 141. The vacuum pump 143 exhausts the interior of the processing container 11 via the exhaust pipe 141. The vacuum pump 143 may include a dry pump or a mechanical booster pump.

The branch pipe 144 branches from the exhaust pipe 141. The branch pipe 144 is connected to the exhaust pipe 141 upstream of the opening/closing valve 142. The branch pipe 144 has an inner surface where a material that promotes consumption of the film formation gas is exposed. In this case, the film formation gas that has not been consumed in the processing container 11 is consumed when flowing through the branch pipe 144, and is trapped in the branch pipe 144. Thus, an amount of the film formation gas that reaches the diaphragm vacuum gauge 145 is reduced, and deposition of a film on a diaphragm 145a of the diaphragm vacuum gauge 145 is suppressed. As a result, shift of a zero point of the diaphragm vacuum gauge 145 can be suppressed.

The branch pipe 144 itself is made of, for example, a material that promotes consumption of the film formation gas. The pipe itself may be formed of a different material, and the inner surface thereof may be coated with a material that promotes consumption of the film formation gas. The branch pipe 144 may have an uneven inner surface. In this case, since a contact area between the film formation gas and the material that promotes consumption of the film formation gas becomes large, consumption of the film formation gas is easily promoted.

The material that promotes consumption of the film formation gas may be, for example, a material that promotes decomposition of the film formation gas through a catalytic reaction. The material that promotes consumption of the film formation gas may be a material that is combined with the film formation gas to consume the film formation gas. For example, when the film formation gas is a silane-based gas, nickel (Ni) may be appropriately used as the material that promotes consumption of the film formation gas. Since decomposition of a silane-based gas is promoted by nickel as a catalyst and the silane-based gas is converted into nickel silicide (NiSi) by being brought into contact with nickel, consumption of the silane-based gas is promoted. When the film formation gas is a silane-based gas, the material that promotes consumption of the film formation gas may be platinum (Pt).

The diaphragm vacuum gauge 145 is connected to the branch pipe 144. The diaphragm vacuum gauge 145 measures a pressure inside the processing container 11. The diaphragm vacuum gauge 145 measures a pressure in a measurement pressure chamber A2 based on a pressure difference between an internal pressure of a reference pressure chamber A1 and an internal pressure of the measurement pressure chamber A2. The diaphragm vacuum gauge 145 detects the pressure difference between the internal pressure of the reference pressure chamber A1 and the internal pressure of the measurement pressure chamber A2 based on an amount of deformation of the diaphragm 145a disposed at a boundary between the reference pressure chamber A1 and the measurement pressure chamber A2.

The reference pressure chamber A1 is a sealed space isolated from the outside of the diaphragm vacuum gauge 145. The reference pressure chamber A1 may be, for example a space having a high degree of vacuum. The measurement pressure chamber A2 is in communication with the interior of the processing container 11 via the branch pipe 144 and the exhaust pipe 141. The measurement pressure chamber A2 changes its internal pressure in accordance with pressure fluctuations in the processing container 11.

The diaphragm vacuum gauge 145 includes the diaphragm 145a, a detector 145b, and a communicator 145c.

The diaphragm 145a is deformed by the pressure difference between the reference pressure chamber A1 and the measurement pressure chamber A2. The diaphragm 145a is disposed inside the detector 145b. For example, a stainless steel diaphragm, a silicon diaphragm, a ceramic diaphragm, or a sapphire diaphragm may be used as the diaphragm 145a. As a method of measuring deformation of the diaphragm 145a, a capacitance method, a piezoelectric method, an optical method, or any other method capable of detecting deformation may be used.

The detector 145b forms the reference pressure chamber A1. The detector 145b has, for example, a cylindrical shape. The diaphragm 145a is disposed inside the cylindrical shape of the detector 145b.

The communicator 145c allows the diaphragm 145a and the measurement pressure chamber A2 to communicate with each other. The communicator 145c has, for example, a circular tube shape. An interior of the communicator 145c is in communication with an interior of the branch pipe 144.

The pipe heater 146 is provided in the exhaust pipe 141 upstream of the vacuum pump 143. The pipe heater 146 heats the exhaust pipe 141 upstream of the vacuum pump 143. The exhaust pipe 141 suppresses a decrease in temperature of a gas discharged from the processing container 11 when the gas flows through the exhaust pipe 141. The pipe heater 146 may not be provided.

The pipe heater 147 is provided in the branch pipe 144. The pipe heater 147 heats the branch pipe 144. By heating the branch pipe 144, consumption of the film formation gas flowing through the branch pipe 144 is easily promoted. For example, when the film formation gas is a silane-based gas, by heating the branch pipe 144 to 200 degrees C. by the pipe heater 147, decomposition of the silane-based gas using nickel as a catalyst is promoted, and nickel silicidation, which is generated when the silane-based gas is brought into contact with nickel, is promoted.

The controller 19 controls operations of respective components of the processing apparatus 1. For example, the controller 19 controls opening and closing the opening/closing valves 123, 133, and 142. The controller 19 may be, for example, a computer. A computer program for executing operations of respective components of the processing apparatus 1 is stored in a non-transitory computer-readable storage medium. The storage medium may be a flexible disk, a compact disk, a hard disk, flash memory, a DVD, or the like.

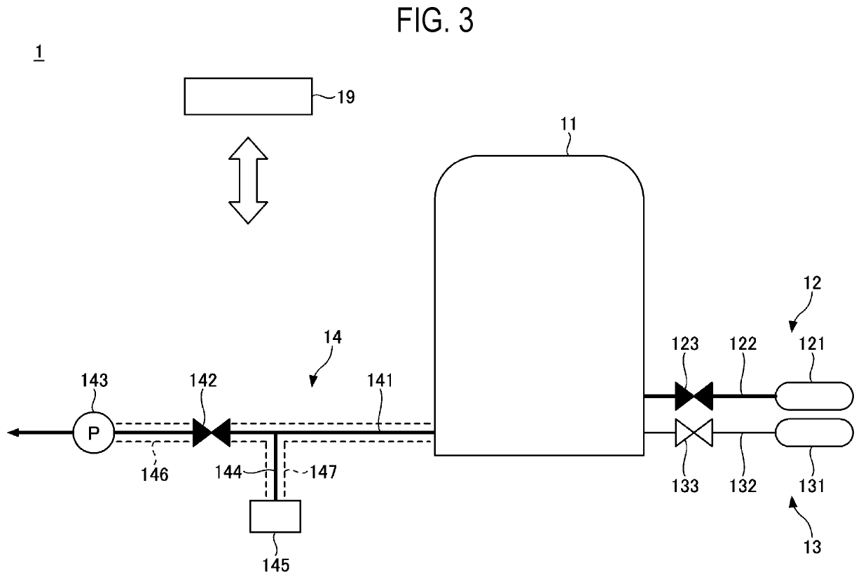

With reference to FIG. 3, a processing method performed in the processing apparatus 1 will be described. FIG. 3 is a schematic view illustrating a processing method according to the first embodiment, and shows a flow of a film formation gas when performing a film formation process on a substrate accommodated in the processing container 11. In FIG. 3, opening/closing valves in an open state are indicated in black, and opening/closing valves in a closed state are indicated in white. In FIG. 3, a path through which the film formation gas flows is indicated by a thick solid line.

The film formation process is performed in a state in which a substrate is accommodated in the processing container 11. In the film formation process, a film formation gas is supplied into the processing container 11. Specifically, as illustrated in FIG. 3, the opening/closing valves 123 and 142 are in the open state, and the opening/closing valve 133 is in the closed state. Thus, the film formation gas in the film formation gas source 121 is supplied into the processing container 11 via the film formation gas supply path 122. A film is formed in the processing container 11 by the film formation gas. At this time, the pressure in the processing container 11 is measured by the diaphragm vacuum gauge 145. The film formation gas that has not been consumed in the processing container 11 is exhausted from the processing container 11 via the exhaust pipe 141. A part of the film formation gas that has not been consumed in the processing container 11 flows toward the diaphragm vacuum gauge 145 via the branch pipe 144. Here, the branch pipe 144 has the inner surface where a material that promotes consumption of the film formation gas is exposed. In this case, the film formation gas is consumed while flowing through the branch pipe 144, and is trapped in the branch pipe 144. Thus, an amount of the film formation gas that reaches the diaphragm vacuum gauge 145 is reduced, and deposition of a film on the diaphragm 145a of the diaphragm vacuum gauge 145 is suppressed. As a result, shift of the zero point of the diaphragm vacuum gauge 145 can be suppressed.

As described above, according to the first embodiment, the branch pipe 144 provided between the exhaust pipe 141 and the diaphragm vacuum gauge 145 has the inner surface where the material that promotes consumption of the film formation gas is exposed. In this case, the film formation gas that has not been consumed in the processing container 11 is consumed when flowing through the branch pipe 144, and is trapped in the branch pipe 144. Thus, the amount of the film formation gas that reaches the diaphragm vacuum gauge 145 is reduced, and the deposition of the film on the diaphragm 145a of the diaphragm vacuum gauge 145 is suppressed. As a result, the shift of the zero point of the diaphragm vacuum gauge 145 can be suppressed.

In addition, in the first embodiment, the case, in which the branch pipe 144 has the inner surface where the material that promotes consumption of the film formation gas is exposed, has been described, but the present disclosure is not limited thereto. For example, the exhaust pipe 141 upstream of a position connected to the branch pipe 144 may have an inner surface where the material that promotes consumption of the film formation gas is exposed. In this case, the film formation gas that has not been consumed in the processing container 11 is trapped in the exhaust pipe 141.

### Second Embodiment

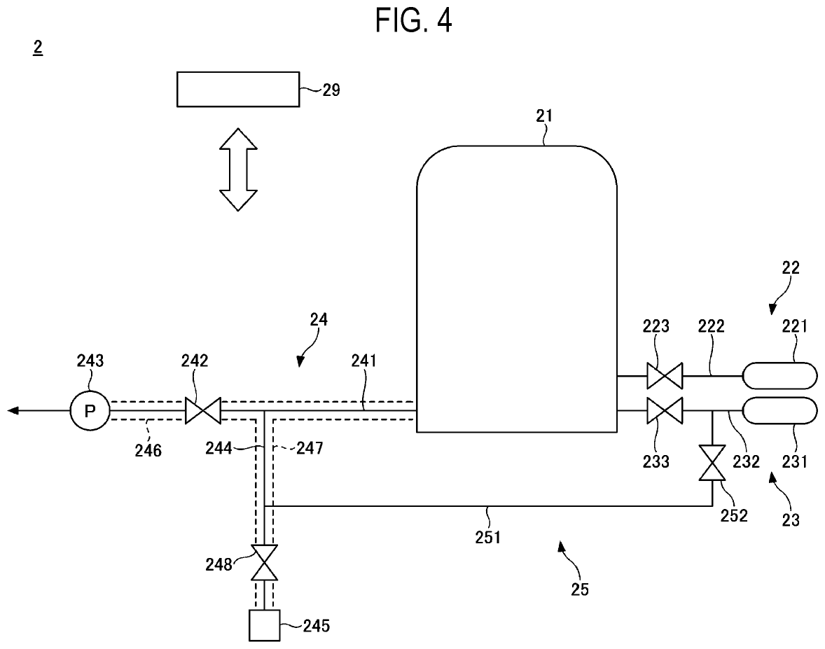

With reference to FIG. 4, a processing apparatus 2 according to a second embodiment will be described. FIG. 4 is a schematic view illustrating the processing apparatus 2 according to the second embodiment. As illustrated in FIG. 4, the processing apparatus 2 differs from the processing apparatus 1 in that the processing apparatus 2 includes a bypass 25. The other configuration of the processing apparatus 2 may be the same as that of the processing apparatus 1. Hereinafter, differences from the processing apparatus 1 will be mainly described.

The processing apparatus 2 includes a processing container 21, a film formation gas supply 22, a cleaning gas supply 23, an exhauster 24, a bypass 25, and a controller 29.

The processing container 21 may be the same as the processing container 11.

The film formation gas supply 22 includes a film formation gas source 221, a film formation gas supply path 222, and an opening/closing valve 223. The film formation gas source 221, the film formation gas supply path 222, and the opening/closing valve 223 may be the same as the film formation gas source 121, the film formation gas supply path 122, and the opening/closing valve 123, respectively.

The cleaning gas supply 23 includes a cleaning gas source 231, a cleaning gas supply path 232, and an opening/closing valve 233. The cleaning gas source 231, the cleaning gas supply path 232, and the opening/closing valve 233 may be the same as the cleaning gas source 131, the cleaning gas supply path 132, and the opening/closing valve 133, respectively.

The exhauster 24 includes an exhaust pipe 241, an opening/closing valve 242, a vacuum pump 243, a branch pipe 244, a diaphragm vacuum gauge 245, pipe heaters 246 and 247, and an opening/closing valve 248. The exhaust pipe 241, the opening/closing valve 242, the vacuum pump 243, the branch pipe 244, the diaphragm vacuum gauge 245, and the pipe heaters 246 and 247 may be the same as the exhaust pipe 141, the opening/closing valve 142, the vacuum pump 143, the branch pipe 144, the diaphragm vacuum gauge 145, and the pipe heaters 146 and 147, respectively.

The opening/closing valve 248 is provided in the branch pipe 244. The opening/closing valve 248 switches a communication state between the exhaust pipe 241 and the diaphragm vacuum gauge 245.

The bypass 25 includes a bypass path 251 and an opening/closing valve 252.

The bypass path 251 interconnects the cleaning gas supply path 232 between the cleaning gas source 231 and the opening/closing valve 233 and the branch pipe 244 between a position connected to the exhaust pipe 241 and the opening/closing valve 248. The bypass path 251 supplies the cleaning gas from the cleaning gas source 231 directly to the branch pipe 244 without going through an interior of the processing container 21. In this case, the cleaning gas is supplied to the branch pipe 244 without being consumed in the processing container 21. In addition, a flow of the cleaning gas is formed from the branch pipe 244 toward the exhaust pipe 241. Thus, deposits in the branch pipe 244 can be efficiently removed. As a result, a replacement cycle of the branch pipe 244 can be lengthened. The deposits include, for example, deposits that are deposited when the film formation gas is trapped in the branch pipe 244. The opening/closing valve 252 is provided in the bypass path 251. The opening/closing valve 252 switches a communication state between the cleaning gas supply path 232 and the branch pipe 244.

The controller 29 controls operations of respective components of the processing apparatus 2. For example, the controller 29 controls opening and closing the opening/closing valves 223, 233, 242, 248, and 252. The controller 29 may be, for example, a computer. A computer program for executing operations of respective components of the processing apparatus 2 is stored in a non-transitory computer-readable storage medium. The storage medium may be a flexible disk, a compact disk, a hard disk, flash memory, a DVD, or the like.

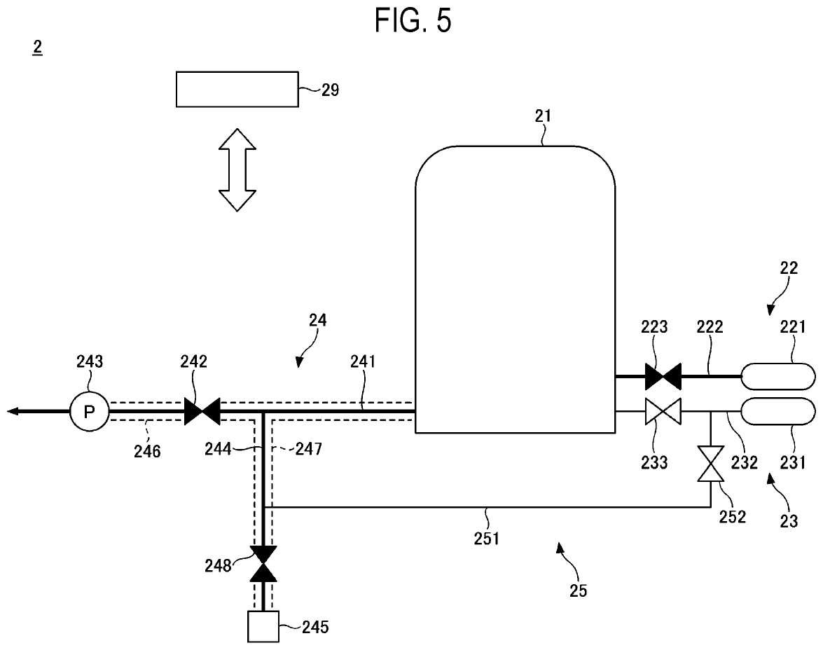

An example of a processing method performed in the processing apparatus 2 will be described with reference to FIG. 5. FIG. 5 is a schematic view illustrating a processing method according to the second embodiment, and shows a flow of the film formation gas when performing a film formation process on a substrate accommodated in the processing container 21 is illustrated. In FIG. 5, opening/closing valves in an open state are indicated in black, and opening/closing valves in a closed state are indicated in white. In FIG. 5, a path through which the film formation gas flows is indicated by a thick solid line.

The film formation process is performed in a state in which a substrate is accommodated in the processing container 21. In the film formation process, a film formation gas is supplied into the processing container 21. Specifically, as illustrated in FIG. 5, the opening/closing valves 223, 242, and 248 are in the open state, and the opening/closing valves 233 and 252 are in the closed state. Thus, the film formation gas in the film formation gas source 221 is supplied into the processing container 21 via the film formation gas supply path 222. A film is formed in the processing container 21 by the film formation gas. At this time, a pressure in the processing container 21 is measured by the diaphragm vacuum gauge 245. The film formation gas that has not been consumed in the processing container 21 is exhausted from the processing container 21 via the exhaust pipe 241. A part of the film formation gas that has not been consumed in the processing container 21 flows toward the diaphragm vacuum gauge 245 via the branch pipe 244. Here, the branch pipe 244 has an inner surface where a material that promotes consumption of the film formation gas is exposed. In this case, the film formation gas is consumed while flowing through the branch pipe 244, and is trapped in the branch pipe 244. Thus, an amount of the film formation gas that reaches the diaphragm vacuum gauge 245 is reduced, and deposition of a film on the diaphragm of the diaphragm vacuum gauge 245 is suppressed. As a result, shift of a zero point of the diaphragm vacuum gauge 245 can be suppressed.

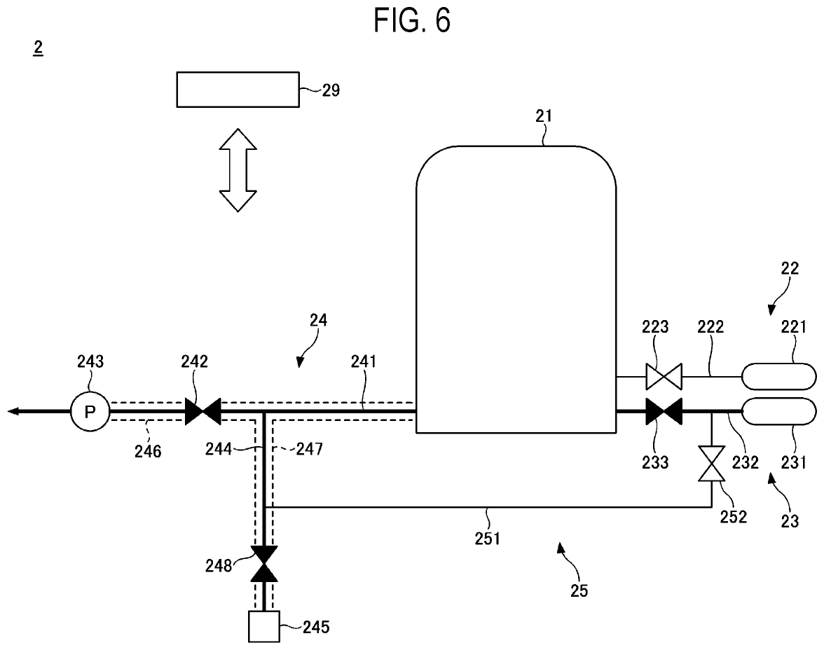

Another example of a processing method performed in the processing apparatus 2 will be described with reference to FIG. 6. FIG. 6 is a schematic view illustrating a processing method according to the second embodiment, and shows a flow of a cleaning gas when performing a chamber-cleaning process to remove deposits in the processing container 21. In FIG. 6, opening/closing valves in an open state are indicated in black, and opening/closing valves in a closed state are indicated in white. In FIG. 6, a path through which the cleaning gas flows is indicated by a thick solid line.

The chamber-cleaning process is performed in a state in which no substrate is present in the processing container 21. In the chamber-cleaning process, a cleaning gas is supplied into the processing container 21. Specifically, the opening/closing valves 233, 242, and 248 are in the open state, and the opening/closing valves 223 and 252 are in the closed state. Thus, the cleaning gas in the cleaning gas source 231 is supplied into the processing container 21 via the cleaning gas supply path 232. The cleaning gas that has not been consumed in the processing container 21 is exhausted from the processing container 21 via the exhaust pipe 241. Deposits in the processing container 21 are etched by the cleaning gas, and are discharged from the processing container 21 via the exhaust pipe 241 together with the cleaning gas.

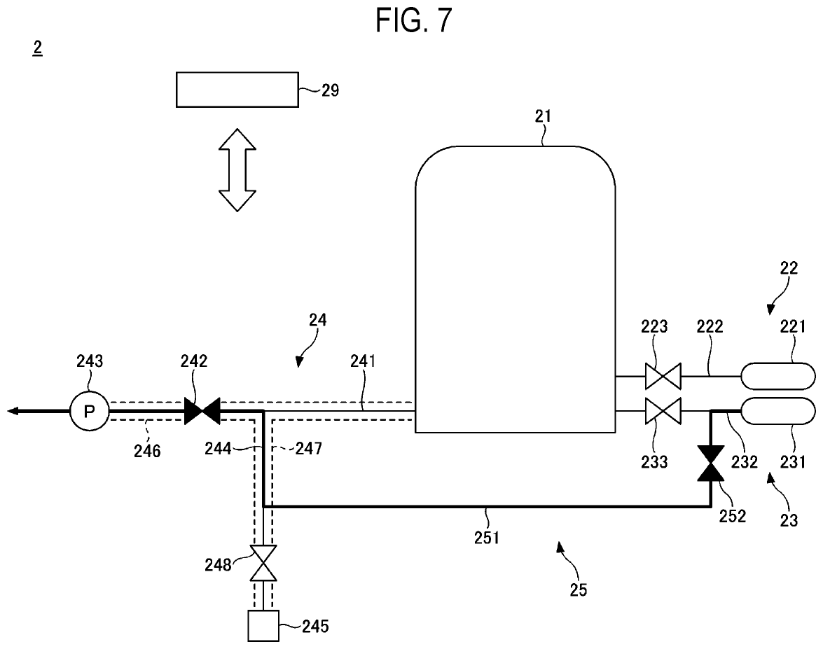

Another example of a processing method performed in the processing apparatus 2 will be described with reference to FIG. 7. FIG. 7 is a schematic view illustrating a processing method according to the second embodiment, and shows a flow of a cleaning gas when performing a pipe-cleaning process to remove deposits in the branch pipe 244. In FIG. 7, opening/closing valves in an open state are indicated in black, and opening/closing valves in a closed state are indicated in white. In FIG. 7, a path through which the cleaning gas flows is indicated by a thick solid line.

In the pipe-cleaning process, a cleaning gas is supplied into the branch pipe 244. Specifically, the opening/closing valves 252 and 242 are in the open state, and the opening/closing valves 223, 233, and 248 are in the closed state. Thus, the cleaning gas in the cleaning gas source 231 is supplied into the branch pipe 244 via the bypass path 251 without going through the interior of the processing container 21. The cleaning gas supplied into the branch pipe 244 is exhausted via the exhaust pipe 241. Deposits in the branch pipe 244 are etched by the cleaning gas, and are removed from the branch pipe 244 via the exhaust pipe 241 together with the cleaning gas. As a result, the replacement cycle of the branch pipe 244 can be lengthened.

As described above, according to the second embodiment, the branch pipe 244 provided between the exhaust pipe 241 and the diaphragm vacuum gauge 245 has the inner surface where the material that promotes consumption of the film formation gas is exposed. Accordingly, the same effects as in the first embodiment are achieved.

In addition, according to the second embodiment, the bypass 25 that interconnects the cleaning gas supply 23 and the branch pipe 244 is provided. Thus, it is possible to supply the cleaning gas from the cleaning gas source 231 directly to the branch pipe 244 without going through the interior of the processing container 21. In this case, the cleaning gas is supplied to the branch pipe 244 without being consumed in the processing container 21. In addition, a flow of the cleaning gas is formed from the branch pipe 244 toward the exhaust pipe 241. Thus, deposits in the branch pipe 244 can be efficiently removed. As a result, the replacement cycle of the branch pipe 244 can be lengthened.

In addition, in the second embodiment, a case, in which the branch pipe 244 has the inner surface where the material that promotes consumption of the film formation gas is exposed, has been described, but the present disclosure is not limited thereto. For example, the exhaust pipe 241 upstream of the position connected to the branch pipe 244 may have an inner surface where the material that promotes consumption of the film formation gas is exposed. In this case, the film formation gas that has not been consumed in the processing container 21 is trapped in the exhaust pipe 241.

### Third Embodiment

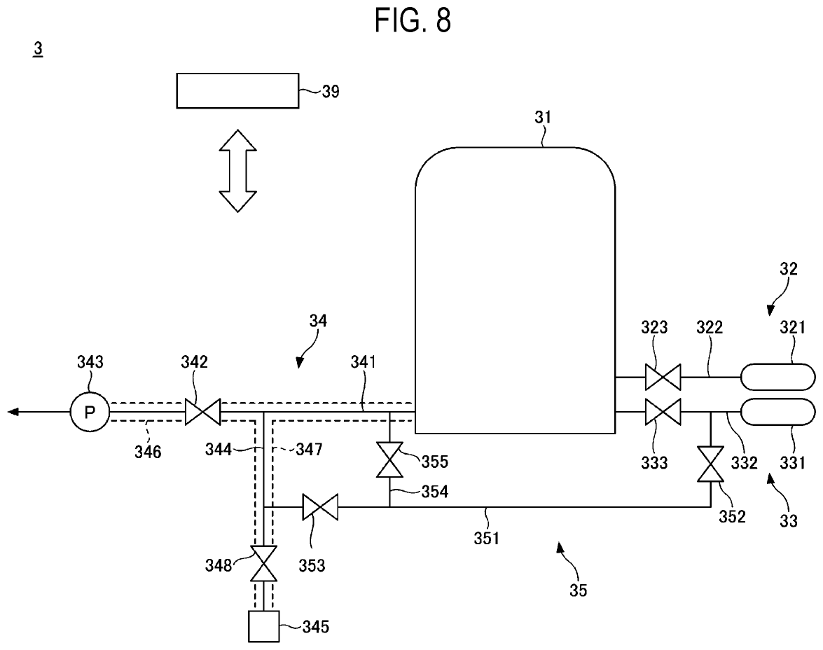

With reference to FIG. 8, a processing apparatus 3 according to a third embodiment will be described. FIG. 8 is a schematic view illustrating the processing apparatus 3 according to the third embodiment. As illustrated in FIG. 8, the processing apparatus 3 differs from the processing apparatus 1 in that both an exhaust pipe 341 and a branch pipe 344 have inner surfaces where a material that promotes consumption of the film formation gas is exposed, and the processing apparatus 3 further includes a bypass 35. The other configuration of the processing apparatus 3 may be the same as that of the processing apparatus 1. Hereinafter, differences from the processing apparatus 1 will be mainly described.

The processing apparatus 3 includes a processing container 31, a film formation gas supply 32, a cleaning gas supply 33, an exhauster 34, a bypass 35, and a controller 39.

The processing container 31 may be the same as the processing container 11.

The film formation gas supply 32 includes a film formation gas source 321, a film formation gas supply path 322, and an opening/closing valve 323. The film formation gas source 321, the film formation gas supply path 322, and the opening/closing valve 323 may be the same as the film formation gas source 121, the film formation gas supply path 122, and the opening/closing valve 123, respectively.

The cleaning gas supply 33 includes a cleaning gas source 331, a cleaning gas supply path 332, and an opening/closing valve 333. The cleaning gas source 331, the cleaning gas supply path 332, and the opening/closing valve 333 may be the same as the cleaning gas source 131, the cleaning gas supply path 132, and the opening/closing valve 133, respectively.

The exhauster 34 includes an exhaust pipe 341, an opening/closing valve 342, a vacuum pump 343, a branch pipe 344, a diaphragm vacuum gauge 345, pipe heaters 346 and 347, and an opening/closing valve 348.

The exhaust pipe 341 has an inner surface where a material that promotes consumption of the film formation gas is exposed. In this case, the film formation gas that has not been consumed in the processing container 31 is consumed when flowing through the exhaust pipe 341, and is trapped in the exhaust pipe 341. Thus, an amount of the film formation gas that reaches the diaphragm vacuum gauge 345 is reduced, and deposition of a film on the diaphragm of the diaphragm vacuum gauge 345 is suppressed. As a result, shift of a zero point of the diaphragm vacuum gauge 345 can be suppressed.

The opening/closing valve 342, the vacuum pump 343, the branch pipe 344, the diaphragm vacuum gauge 345, and the pipe heaters 346 and 347 may be the same as the opening/closing valve 142, the vacuum pump 143, the branch pipe 144, the diaphragm vacuum gauge 145, and the pipe heaters 146 and 147, respectively.

The opening/closing valve 348 is provided in the branch pipe 344. The opening/closing valve 348 switches a communication state between the exhaust pipe 341 and the diaphragm vacuum gauge 345.

The bypass 35 includes a bypass path 351, an opening/closing valve 352, an opening/closing valve 353, a branch path 354, and an opening/closing valve 355.

The bypass path 351 interconnects the cleaning gas supply path 332 between the cleaning gas source 331 and the opening/closing valve 333 and the branch pipe 344 between a position connected to the exhaust pipe 341 and the opening/closing valve 348. The bypass path 351 supplies the cleaning gas from the cleaning gas source 331 directly to the branch pipe 344 without going through an interior of the processing container 31. In this case, the cleaning gas is supplied to the branch pipe 344 without being consumed in the processing container 31. In addition, a flow of the cleaning gas is formed from the branch pipe 344 toward the exhaust pipe 341. Thus, deposits in the branch pipe 344 can be efficiently removed. As a result, a replacement cycle of the branch pipe 344 can be lengthened. The deposits include, for example, deposits that are deposited when the film formation gas is trapped in the branch pipe 344.

The opening/closing valve 352 is provided in the bypass path 351. The opening/closing valve 352 switches a communication state between the cleaning gas supply path 332 and the branch pipe 344.

The opening/closing valve 353 is provided in the bypass path 351 downstream of the opening/closing valve 352. The opening/closing valve 353 switches a communication state between the cleaning gas supply path 332 and the branch pipe 344.

The branch path 354 interconnects the bypass path 351 between the opening/closing valve 352 and the opening/closing valve 353 and the exhaust pipe 341 upstream of a position connected to the branch pipe 344. A location where the branch path 354 and the exhaust pipe 341 are connected to each other may be, for example, in a vicinity of the processing container 31. The branch path 354 supplies the cleaning gas in the cleaning gas source 331 directly to the exhaust pipe 341 without going through an interior of the processing container 31. In this case, since the cleaning gas is directly supplied to the exhaust pipe 341 without being consumed in the processing container 31, deposits in the exhaust pipe 341 can be efficiently removed. As a result, a replacement cycle of the exhaust pipe 341 can be lengthened. The deposits include, for example, deposits that are deposited when the film formation gas is trapped in the exhaust pipe 341.

The opening/closing valve 355 is provided in the branch path 354. The opening/closing valve 355 switches a communication state between the bypass path 351 and the exhaust pipe 341.

The controller 39 controls operations of respective components of the processing apparatus 3. For example, the controller 39 controls opening and closing the opening/closing valves 323, 333, 342, 348, 352, 353, and 355. The controller 39 may be, for example, a computer. A computer program for executing operations of respective components of the processing apparatus 3 is stored in a non-transitory computer-readable storage medium. The storage medium may be a flexible disk, a compact disk, a hard disk, flash memory, a DVD, or the like.

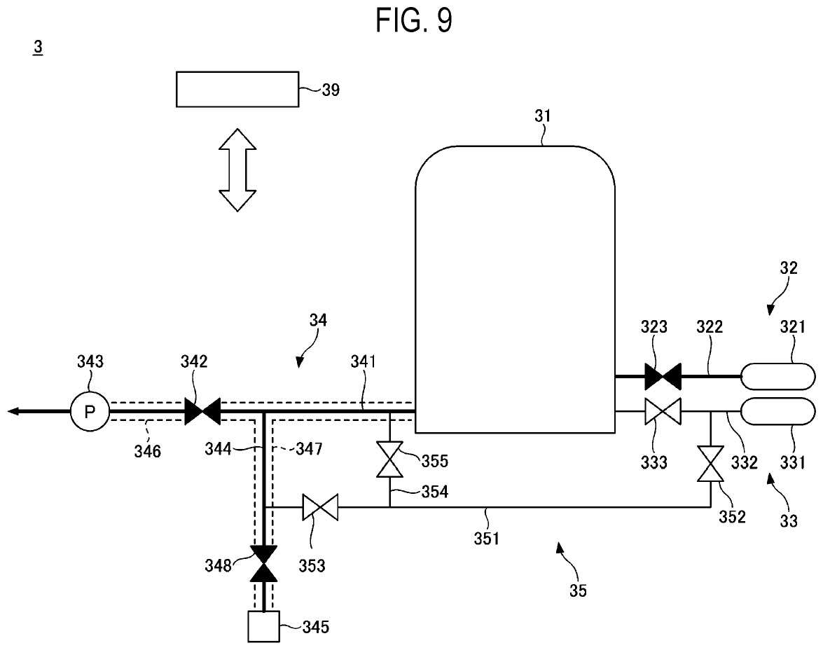

An example of a processing method performed in the processing apparatus 3 will be described with reference to FIG. 9. FIG. 9 is a schematic view illustrating a processing method according to the third embodiment, and shows a flow of a film formation gas when performing a film formation process on a substrate accommodated in the processing container 31. In FIG. 9, opening/closing valves in an open state are indicated in black, and opening/closing valves in a closed state are indicated in white. In FIG. 9, a path through which the film formation gas flows is indicated by a thick solid line.

The film formation process is performed in a state in which a substrate is accommodated in the processing container 31. In the film formation process, a film formation gas is supplied into the processing container 31. Specifically, as illustrated in FIG. 9, the opening/closing valves 323, 342, and 348 are in the open state, and the opening/closing valves 333, 352, 353, and 355 are in the closed state. Thus, the film formation gas in the film formation gas source 321 is supplied into the processing container 31 via the film formation gas supply path 322. A film is formed in the processing container 31 by the film formation gas. At this time, the pressure in the processing container 31 is measured by the diaphragm vacuum gauge 345. The film formation gas that has not been consumed in the processing container 31 is exhausted from the processing container 31 via the exhaust pipe 341. A part of the film formation gas that has not been consumed in the processing container 31 flows toward the diaphragm vacuum gauge 345 via the branch pipe 344. Here, the branch pipe 344 has an inner surface where a material that promotes consumption of the film formation gas is exposed. In this case, the film formation gas is consumed while flowing through the branch pipe 344, and is trapped in the branch pipe 344. Thus, an amount of the film formation gas that reaches the diaphragm vacuum gauge 345 is reduced, and deposition of a film on the diaphragm of the diaphragm vacuum gauge 345 is suppressed. As a result, shift of a zero point of the diaphragm vacuum gauge 345 can be suppressed.

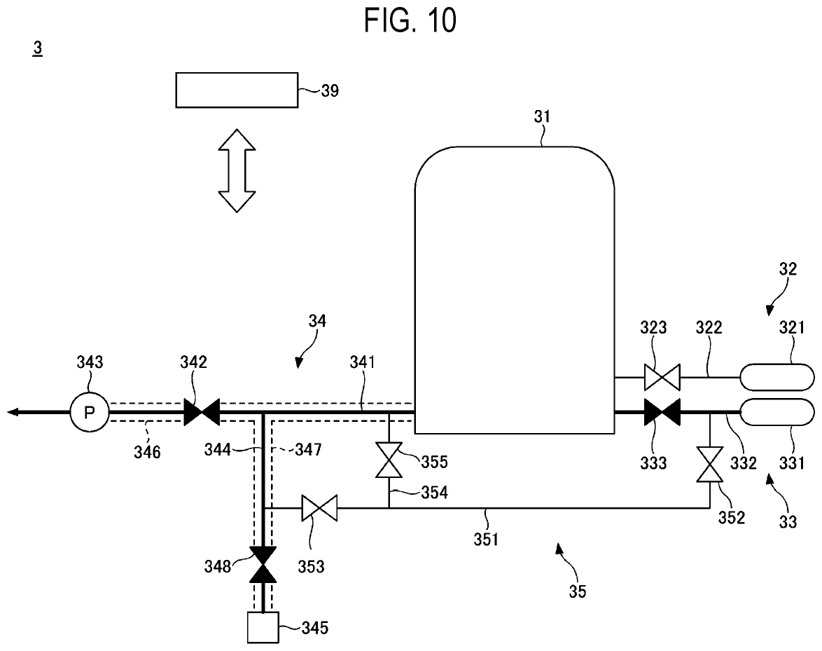

Another example of a processing method performed in the processing apparatus 3 will be described with reference to FIG. 10. FIG. 10 is a schematic view illustrating the processing method according to the third embodiment, and shows a flow of a cleaning gas when performing a chamber-cleaning process to remove deposits in the processing container 31. In FIG. 10, opening/closing valves in the open state are indicated in black, and opening/closing valves in the closed state are indicated in white. In FIG. 10, a path through which the cleaning gas flows is indicated by a thick solid line.

The chamber-cleaning process is performed in a state in which no substrate is present in the processing container 31. In the chamber-cleaning process, a cleaning gas is supplied into the processing container 31. Specifically, the opening/closing valves 333, 342, and 348 are in the open state, and the opening/closing valves 323, 352, 353, and 355 are in the closed state. Thus, the cleaning gas in the cleaning gas source 331 is supplied into the processing container 31 via the cleaning gas supply path 332. The cleaning gas that has not been consumed in the processing container 31 is exhausted from the processing container 31 via the exhaust pipe 341. Deposits in the processing container 31 are etched by the cleaning gas, and are discharged from the processing container 31 via the exhaust pipe 341 together with the cleaning gas.

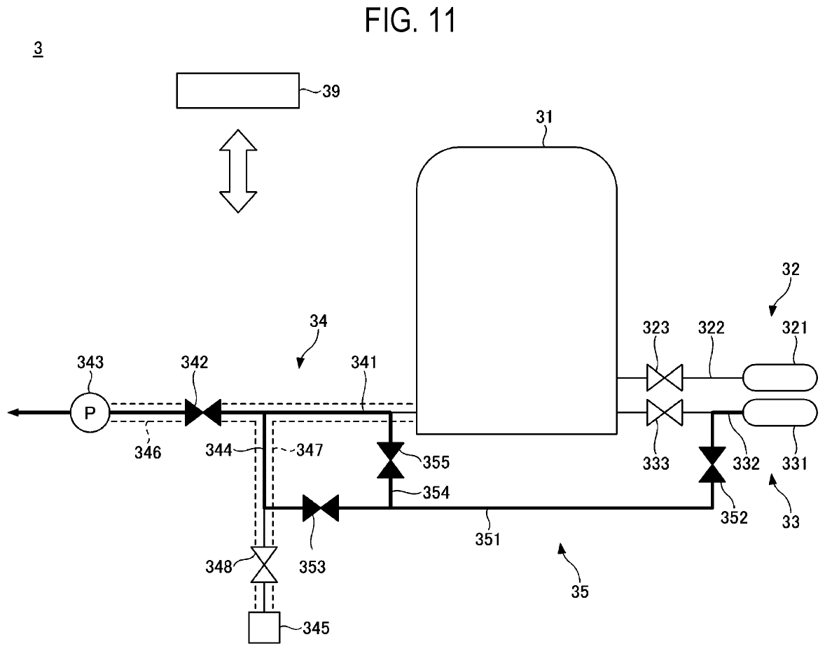

Another example of a processing method performed in the processing apparatus 3 will be described with reference to FIG. 11. FIG. 11 is a schematic view illustrating the processing method according to the third embodiment, and shows a flow of a cleaning gas when performing a pipe-cleaning process to remove deposits in the branch pipe 344. In FIG. 11, opening/closing valves in the open state are indicated in black, and opening/closing valves in the closed state are indicated in white. In FIG. 11, a path through which the cleaning gas flows is indicated by a thick solid line.

In the pipe-cleaning process, a cleaning gas is supplied into the exhaust pipe 341 and the branch pipe 344. Specifically, the opening/closing valves 352, 353, 355, and 342 are in the open state, and the opening/closing valves 323, 333, and 348 are in the closed state. Thus, the cleaning gas in the cleaning gas source 331 is supplied into the exhaust pipe 341 via the bypass path 351 and the branch path 354 without going through the interior of the processing container 31. Deposits in the exhaust pipe 341 are etched by the cleaning gas, and are removed from the exhaust pipe 341 together with the cleaning gas. Thus, the replacement cycle of the exhaust pipe 341 can be lengthened. In addition, the cleaning gas in the cleaning gas source 331 is supplied into the branch pipe 344 via the bypass path 351 without going through the interior of the processing container 31. The cleaning gas supplied into the branch pipe 344 is exhausted via the exhaust pipe 341. Deposits in the branch pipe 344 are etched by the cleaning gas, and are removed from the branch pipe 344 via the exhaust pipe 341 together with the cleaning gas. As a result, the replacement cycle of the branch pipe 344 can be lengthened.

As described above, according to the third embodiment, the branch pipe 344 provided between the exhaust pipe 341 and the diaphragm vacuum gauge 345 has the inner surface where the material that promotes consumption of the film formation gas is exposed. Accordingly, the same effects as in the first embodiment are achieved.

In addition, according to the third embodiment, the exhaust pipe 341 has the inner surface where the material that promotes consumption of the film formation gas is exposed. Accordingly, the film formation gas that has not been consumed in the processing container 31 is consumed when flowing through the exhaust pipe 341, and is trapped in the exhaust pipe 341. Thus, an amount of the film formation gas that reaches the diaphragm vacuum gauge 345 is reduced, and deposition of a film on the diaphragm of the diaphragm vacuum gauge 345 is suppressed. As a result, the shift of the zero point of the diaphragm vacuum gauge 345 can be suppressed.

In addition, according to the third embodiment, the bypass 35 that interconnects the cleaning gas supply 33 and the branch pipe 344 is provided. Thus, it is possible to supply the cleaning gas from the cleaning gas source 331 directly to the branch pipe 344 without going through the interior of the processing container 31. In this case, the cleaning gas is supplied to the branch pipe 344 without being consumed in the processing container 31. In addition, a flow of the cleaning gas is formed from the branch pipe 344 toward the exhaust pipe 341. Thus, deposits in the branch pipe 344 can be efficiently removed. As a result, the replacement cycle of the branch pipe 344 can be lengthened.

In addition, according to the third embodiment, the branch path 354 that interconnects the bypass path 351 and the exhaust pipe 341 is provided. Thus, the cleaning gas in the cleaning gas source 331 can be directly supplied to the exhaust pipe 341 without going through the interior of the processing container 31. In this case, the cleaning gas is supplied directly to the exhaust pipe 341 without being consumed in the processing container 31. Thus, deposits in the exhaust pipe 341 can be efficiently removed. As a result, the replacement cycle of the exhaust pipe 341 can be lengthened.

In addition, in the third embodiment, a case, in which the exhaust pipe 341 and the branch pipe 344 have inner surfaces where the material that promotes consumption of the film formation gas is exposed, has been described, but the present disclosure is not limited thereto. For example, the branch pipe 344 may not have an inner surface where the material that promotes consumption of a film formation gas is exposed. In this case, the bypass path 351 may not be connected to the branch pipe 344.

According to the present disclosure, it is possible to suppress a film from being deposited on a diaphragm of a diaphragm vacuum gauge.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing apparatus comprising:
a processing container configured to be depressurized;
a film formation gas supply path configured to supply a film formation gas into the processing container;
an exhaust pipe connected to the processing container and configured to exhaust the film formation gas in the processing container;
a branch pipe branching from the exhaust pipe; and
a diaphragm vacuum gauge connected to the branch pipe,
wherein at least one of the exhaust pipe or the branch pipe has an inner surface where a material that promotes consumption of the film formation gas is exposed.

2. The processing apparatus of claim 1, wherein at least one of the exhaust pipe or the branch pipe is made of the material that promotes the consumption of the film formation gas.

3. The processing apparatus of claim 2, wherein the film formation gas is a silane-based gas, and
wherein the material that promotes the consumption of the film formation gas is nickel.

4. The processing apparatus of claim 1, wherein at least one of the exhaust pipe or the branch pipe has an inner surface coated with the material that promotes the consumption of the film formation gas.

5. The processing apparatus of claim 1, further comprising a pipe heater configured to heat at least one of the exhaust pipe or the branch pipe.

6. The processing apparatus of claim 1, further comprising:
a cleaning gas supply path configured to supply a cleaning gas into the processing container; and
a bypass path interconnecting the cleaning gas supply path and the branch pipe.

7. The processing apparatus of claim 1, wherein the film formation gas is a silane-based gas, and
wherein the material that promotes the consumption of the film formation gas is nickel.

8. A processing method in a processing apparatus, wherein the processing apparatus comprises a processing container configured to be depressurized, a film formation gas supply path configured to supply a film formation gas into the processing container, a cleaning gas supply path configured to supply a cleaning gas into the processing container, an exhaust pipe connected to the processing container and configured to exhaust the film formation gas in the processing container, a branch pipe branching from the exhaust pipe, a diaphragm vacuum gauge connected to the branch pipe, and a bypass path interconnecting the cleaning gas supply path and the branch pipe,
wherein the branch pipe has an inner surface where a material that promotes consumption of the film formation gas is exposed,
wherein the processing method comprises:
forming a film on a substrate accommodated in the processing container by supplying the film formation gas from the film formation gas supply path into the processing container, while measuring a pressure in the processing container with the diaphragm vacuum gauge; and
removing deposits deposited in the branch pipe during the forming the film by supplying the cleaning gas to the branch pipe from the cleaning gas supply path via the bypass path.

9. The processing method of claim 8, further comprising removing deposits deposited in the processing container during the forming the film by supplying the cleaning gas into the processing container from the cleaning gas supply path.

10. The processing method of claim 9, wherein the film formation gas is a silane-based gas, and
wherein the material that promotes the consumption of the film formation gas is nickel.

11. The processing method of claim 8, wherein the removing the deposits deposited in the branch pipe comprises heating the branch pipe.

12. The processing method of claim 8, wherein the film formation gas is a silane-based gas, and
wherein the material that promotes the consumption of the film formation gas is nickel.
